(19) United States
(12) Patent Application Publication
(10) Pub. No.: US 2025/0012573 A1
(43) Pub. Date: Jan. 9, 2025

(54) Method and Apparatus for Determining a Motion of a Vehicle

(71) Applicant: Robert Bosch GmbH, Stuttgart (DE)

(72) Inventors: Jorge Juan Robles, Leonberg (DE); Gunther Lang, Stuttgart (DE); Steffen Baab, Gensingen (DE)

(21) Appl. No.: 18/753,515

(22) Filed: Jun. 25, 2024

(30) Foreign Application Priority Data
Jul. 7, 2023 (DE) 10 2023 206 461.8

(51) Int. Cl. G01C 21/16

(52) U.S. Cl. CPC G01C 21/16

(57) ABSTRACT

A method for determining a movement of a vehicle includes (i) reading in a first sensor signal via an interface to a first inertial sensor of the vehicle and a second sensor signal via an interface to a second inertial sensor of the vehicle, (ii) ascertaining a first level signal, representing a noise level of the first sensor signal and a second level signal representing a noise level of the second sensor signal using the first sensor signal, the second sensor signal and an activity signal representing an activity of the vehicle, and (iii) determining a movement signal representing the movement of the vehicle using the first sensor signal, the second sensor signal, the first level signal and the second level signal.

This application claims priority under 35 U.S.C. § 119 to patent application no. DE 10 2023 206 461.8, filed on Jul. 7, 2023 in Germany, the disclosure of which is incorporated herein by reference in its entirety.

### BACKGROUND

The disclosure relates to a method and apparatus for determining a movement of a vehicle. The subject matter of the present disclosure also relates to a computer program.

Many applications in the field of vehicles, such as autonomous driving functions, require the use of reliable sensor signals.

### SUMMARY

In light of this, with the approach presented here, a method for determining a motion of a vehicle as well as an apparatus which uses this method, and finally a corresponding computer program are proposed. Advantageous embodiments of and improvements to the apparatus specified below are made possible by the measures presented herein.

It can be advantageous to monitor sensor signals from sensors of a vehicle in connection with an activity of the vehicle.

A method for determining a movement of a vehicle comprises the following steps:
reading in a first sensor signal via an interface to a first inertial sensor of the vehicle and a second sensor signal via an interface to a second inertial sensor of the vehicle;
ascertaining a first level signal representing a noise level of the first sensor signal and a second level signal representing a noise level of the second sensor signal using the first sensor signal, the second sensor signal, and an activity signal representing an activity of the vehicle; and
determining a movement signal representing the movement of the vehicle using the first sensor signal, the second sensor signal, the first level signal, and the second level signal.

The vehicle can be a motor vehicle, for example an automatically or manually controlled vehicle. An inertial sensor can be designed as an accelerometer or a rotation rate sensor, for example. The inertial sensors can be of the same or different design. Movement of the vehicle can be understood to mean an acceleration of the entire vehicle or a rotation of the vehicle about a vehicle axis, for example. Use of the level signals can include establishing which of the sensor signals are used to determine the movement and, if necessary, the weighting that is assigned to the sensor signals used. For example, a sensor signal that has a high degree of noise can be excluded from the movement determination, or can be included but given a lower weighting compared to a less noise-compromised sensor signal. The activity of the vehicle can indicate a state of the vehicle that has a predetermined effect on at least one of the sensor signals. For example, the activity can indicate no movement of the vehicle, or that it is driving on a smooth roadway or an unpaved roadway.

The method can comprise a step of providing the activity signal using at least one of the sensor signals. An appropriate evaluation of the sensor signal can be performed for this purpose; for example, a temporal profile in the sensor signal can be compared to reference profiles associated with different activities, or a level of the sensor signal can be compared with threshold values associated with different activities in order to recognize a current activity of the vehicle and to indicate this via the activity signal. Additionally, or alternatively, one or more further signal sources can be used to provide the activity signal.

For example, the at least one sensor signal can be filtered in the providing step, and then a comparison can be made with at least one threshold value. In so doing, the activity of the vehicle can be recognized depending on a result of the comparison. This allows the activity to be recognized quickly and without a great amount of computational effort.

For example, the activity can be recognized as a stopped vehicle, the vehicle driving off-road or the vehicle driving on the highway. Thus, activities that can be clearly differentiated based on different signal profiles of the inertial sensors can be used for the approach described herein.

In the ascertaining step, a first filter for filtering the first sensor signal and a second filter for filtering the second sensor signal can be set using the activity signal. The first sensor signal can be filtered using the first filter to obtain a first filtered sensor signal. The second sensor signal can be filtered using the second filter to obtain a second filtered sensor signal. The first level signal can be ascertained using the first filtered sensor signal and the second level signal can be ascertained using the second filtered sensor signal. The filtering allows sensor signal frequency ranges that have particularly strong noise to be selected. Advantageously, using the activities, the filtering ranges of the filters can be adjusted so that filtering can be done specific to the situation.

In the ascertaining step, the first filtered sensor signal can be quantized to obtain a first quantization value. The second filtered sensor signal can be similarly quantized to obtain a second quantization value, wherein the first level signal can represent the first quantization value and the second level signal can represent the second quantization value. The quantization values are very suitable for evaluating the noise. In ascertaining the quantization values, other characteristics of the filtered sensor signals can be considered, for example a distance between signal spikes, a mean value or a variance. Quantification can be refined in this way.

In the determining step, the first level signal can be compared with a first threshold value defined using the activity signal in order to create a first quality value representing a quality of the first sensor signal. The second level signal can be similarly compared with a second threshold value defined using the activity signal in order to create a second quality value representing a quality of the second sensor signal. Finally, the movement signal can be determined using the first sensor signal, the second sensor signal, the first quality value, and the second quality value. For example, the quantization values associated with the sensor signals can be compared with threshold values in order to determine a good or a bad quality of the sensor signals. For example, sensor signals which have been assigned a poor quality value can be excluded from the determination of the movement signal or they may only enter into the determination of the movement signal with a low weighting.

Additionally, or alternatively, in the determining step a reference value can be determined using the first level signal and the second level signal. A first noise indicator value can be determined as the difference between the first level signal and the reference value, and a second noise indicator value can be determined as the difference between the second level signal and the reference value. In so doing, the movement signal can be determined using the first sensor signal, the second sensor signal, the first noise indicator value, and the second noise indicator value. For example, sensor signals which have been assigned a poor noise indicator value can be excluded from the determination of the movement signal or they may only enter into the determination of the movement signal with a low weighting.

In the determining step, using the first level signal a first error signal can be determined which is indicative of an error state of the first inertial sensor, and using the second level signal a second error signal can be determined which is indicative of an error state of the second inertial sensor. The error signals can be used to deactivate an inertial sensor which has been evaluated as being erroneous, or else flag it as being erroneous, for example.

The steps of the method can be similarly executed when using a plurality of sensor signals of a plurality of inertial sensors. For example, when using sensor signals from three, four, five or more inertial sensors. Accordingly, in the reading-in step, at least one further sensor signal can be read in via an interface to at least one further inertial sensor of the vehicle, and in the ascertaining step, accordingly, at least one further level signal representing a noise level of the at least one further sensor signal can be ascertained using the at least one further sensor signal and the activity signal. Thus, the described approach can be adapted to different sensor configurations.

For example, this method can be implemented in software or hardware, or in a mixed form of software and hardware, for example in a controller.

The approach presented here further provides an apparatus which is designed to perform, control, or implement, in corresponding devices, the steps of a variant of a method presented herein. The object of the present disclosure can also be achieved quickly and efficiently by way of this embodiment variant of the disclosure in the form of an apparatus.

For this purpose, the apparatus can comprise at least one computing unit for processing signals or data, at least one memory unit for storing signals or data, at least one interface to a sensor or an actuator for reading in sensor signals from the sensor or for outputting data or control signals to the actuator, and/or at least one communication interface for reading in or outputting data embedded in a communication protocol. The computing unit can be a signal processor, a microcontroller or the like, for example, and the memory unit can be a flash memory or a magnetic memory unit. The communication interface can be designed to read in or output data in a wireless and/or wired manner, wherein a communication interface capable of reading in or outputting wired data can read in said data from a corresponding data transmission line, for example electrically or optically, or output said data to a corresponding data transmission line.

In the present context, an apparatus can be understood to mean an electrical device that processes sensor signals and outputs control signals and/or data signals as a function thereof. The apparatus can comprise an interface in the form of hardware and/or software. For example, in a hardware design, the interfaces can be part of what is referred to as an ASIC system, which contains a wide variety of apparatus functions. However, it is also possible that the interfaces are separate integrated circuits or consist at least in part of discrete components. In a software design, for example, the interfaces can be software modules provided on a microcontroller in addition to other software modules.

A computer program product or a computer program with program code that can be stored on a machine-readable carrier or storage medium such as a semiconductor memory, a hard disk memory, or an optical memory, and that is used to perform, implement, and/or control the method steps according to one of the embodiments described above is advantageous as well, in particular when the program product or program is executed on a computer or apparatus.

Exemplary embodiments of the approach presented herein are shown in the drawings and explained in greater detail in the following description.

### BRIEF DESCRIPTION OF THE DRAWINGS

FIG. 1 is a schematic representation of a vehicle having an apparatus according to an exemplary embodiment;

FIG. 2 is a block diagram of an ascertaining device according to an exemplary embodiment;

FIG. 3 is a block diagram of an activity recognition device according to an exemplary embodiment;

FIG. 4 is a block diagram of an extraction device according to an exemplary embodiment;

FIG. 5 is a representation of a Root Allan variance according to an exemplary embodiment; and

FIG. 6 is a flow chart of a method according to an exemplary embodiment.

### DETAILED DESCRIPTION

In the following description of advantageous exemplary embodiments of the present disclosure, identical or similar reference signs are used for the elements shown in the various figures that act similarly, in which case a repeated description of these elements has been omitted.

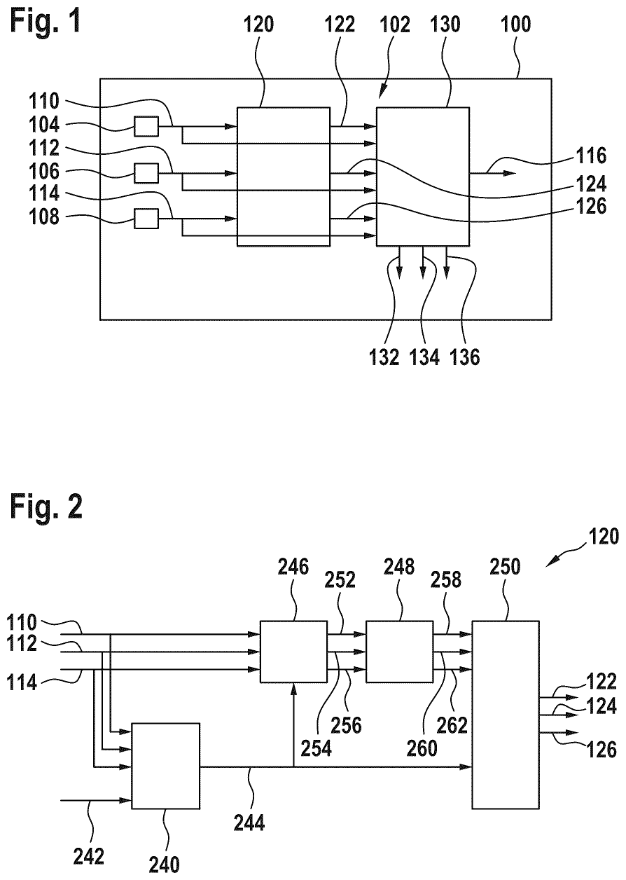

FIG. 1 shows a schematic representation of a vehicle 100 having an apparatus 102 according to an exemplary embodiment. The vehicle 100 is a motor vehicle, for example. The vehicle 100 has a plurality of sensors, here by way of example a first inertial sensor 104, a second inertial sensor 106, and a third inertial sensor 108. Optionally, the inertial sensors 104, 106, 108 are part of the apparatus 102.

The first inertial sensor 104 is designed to provide a first sensor signal 110, the second inertial sensor 106 is designed to provide a second sensor signal 112, and the third inertial sensor 108 is designed to provide a third sensor signal 110. For example, the sensor signals 110, 112, 114 represent temporal profiles of the same acceleration or of different accelerations of the vehicle 100, the accelerations sensed by the inertial sensors 104, 106, 108.

The apparatus 102 is designed to determine, using the sensor signals 110, 112, 114, a movement signal 116 representing a movement of the vehicle. For example, the movement signal 116 is determined based on one of the sensor signals 110, 112, 114 or based on a combination of at least two of the sensor signals 110, 112, 114. The apparatus 102 is designed to account for noise in the sensor signals 110, 112, 114 when selecting the sensor signal or signals 110, 112, 114 used to determine the movement signal 116.

To this end, the apparatus 102 comprises an ascertaining device 120 designed to ascertain a noise level for each of the sensor signals 110, 112, 114. By way of example, ascertaining device 120 is designed to ascertain a first level signal 122 representing a noise level of first sensor signal 110, to ascertain a second level signal 124 representing a noise level of second sensor signal 112, and to ascertain a third level signal 126 representing a noise level of third sensor signal 114. In so doing, the ascertaining device 120 is designed to ascertain the noise level in connection with an activity that the vehicle 100 has carried out while the sensor signals 110, 112, 114 were being generated. Depending on the exemplary embodiment, the ascertaining device 120 is designed to read in an activity signal indicative of the activity, or to itself generate a corresponding activity signal, for example using only the sensor signals 110, 112, 114, or in combination with a further signal, optionally a signal that was read in.

The apparatus 102 comprises a determination device 130 designed to determine the movement signal 116 using the sensor signals 110, 112, 114 and the level signals 122, 124, 126. For example, the determination device 130 is designed to use the level signals 122, 124, 126 as an indicator of noise in the sensor signals 110, 112, 114 or to estimate a quality of the sensor signals 110, 112, 114 based on the level signals 122, 124, 126 and accordingly to select an appropriate combination of the sensor signals 110, 112, 114 for determining the movement signal 116.

According to an exemplary embodiment, the determination device 130 is designed to compare the first level signal 122 with a first threshold value defined using the activity signal so as to create a first quality value representing a quality of the first sensor signal 110, compare the second level signal 124 with a second threshold value defined using the activity signal so as to create a second quality value representing a quality of the second sensor signal 112, and to compare the third level signal 124 with a third threshold value defined using the activity signal so as to create a second quality value representing a quality of the third sensor signal 114. In this case, the movement signal 116 is determined using the first sensor signal 110, the second sensor signal 112, the third sensor signal 114, the first quality value, the second quality value, and the third quality value. Advantageously, the quality values may be used to, for example, recognize any of the sensor signals 110, 112, 114 which is not suitable for determining the movement signal 116, and to not include it at all, or only at a low weighting, as appropriate, in the determination of the movement signal 116.

According to an exemplary embodiment, the determination device 130 is designed to determine a reference value using the first level signal 122, the second level signal 124 and the third level signal 126. The determination device 130 is further designed to determine a first noise indicator value as the difference between the first level signal and the reference value, a second noise indicator value as the difference between the second level signal and the reference value, and a third noise indicator value as the difference between the third level signal and the reference value. Finally, the movement signal 116 is determined using the first sensor signal 110, the second sensor signal 112, the third sensor signal 114, the first noise indicator value, the second noise indicator value, and the third noise indicator value.

Optionally, the determination device 130 is designed to carry out an error check for each of the sensor signals 110, 112, 114, said check able to provide recognition of, for example, an error condition of one of the inertial sensors 104, 106, 108. To this end, according to an exemplary embodiment the determination device 130 is designed to determine, using the first level signal 122, a first error signal 132 indicative of an error state of the first inertial sensor 104, and to determine, using the second level signal 124, a second error signal 134 indicative of an error state of the second inertial sensor 106 and to determine a third error signal 136 indicative of an error state of the third inertial sensor 108. For example, the level signals 122, 124, 126 are compared to one or more suitable safety threshold values.

Even though three inertial sensors 104, 106, 108 are shown in the embodiment shown, the described approach may be employed for any number of sensors and adjusted accordingly.

For example, the described approach is used to recognize and use degradation indicators in algorithms for systems with redundant inertial sensors, such as inertial sensors 104, 106, 108. High-performance inertial measurement units (IMUs) measure physical movement of the vehicle 100 in terms of acceleration and angular velocity and are often used for AD applications that have high demands on signal reliability and accuracy.

Many applications, such as autonomous driving functions, for example, require the use of reliable sensor signals 110, 112, 114. Thus, redundant IMU sensor architectures that measure the same physical event (for example three rotation rate sensors installed on the same printed circuit board) are typically used to recognize sensor failures by monitoring the signal deviations between the redundant signals.

The valid redundant signals are combined (fusion) or a selection algorithm may be implemented to select the “best” final signal from all possibilities in terms of functional retention and signal accuracy.

The redundant sensor sets can have different frequency characteristics; for example, some sensors may have more noise than others. It is clear that the use of signals that have less noise can increase the accuracy of the final signal, in this case the movement signal 116.

Safety thresholds may be set not only for the offset or sensitivity but also for the noise level (or density) of the signals. In these cases, it may also be necessary to monitor the noise level of the signals so as to react appropriately when the noise is above the established safety threshold value. For example, a reaction could involve setting the signal, in this case one of the sensor signals 110, 112, 114, to invalid status if a diagnostic threshold is exceeded.

The approach described here is optionally used along with software-based monitoring to react to the noise level of the sensor signals 110, 112, 114.

The accuracy of the final signal, in this case the movement signal 116, is improved by considering the noise level of the sensor signals 110, 112, 114 in the selection and/or fusion of the final signal.

The information about the activity or situation of the vehicle can be used to recognize known situations in which it is expected that the sensor signals 110, 112, 114 will have a known behavior. This makes it easier to identify components of the sensor signals 110, 112, 114 that can be considered to be compromised. For example, it is known that the sensor signals 110, 112, 114 should be near zero when the vehicle 100 is not moving. If high-frequency signals are present, they may be considered to be contaminated (noise).

Another advantage is that a monitoring mechanism can be implemented to predict the noise level in the sensor signals 110, 112, 114.

The following figures describe exemplary embodiments of function blocks having technical features for implementing the described approach. In the process, the approach is based on using activity information in the noise recognition function, monitoring the noise level to recognize possible errors in the sensors, and using a noise level indicator in the selection and/or fusion of the final signal.

FIG. 2 shows a block diagram of an exemplary embodiment of an ascertaining device 120 of an apparatus for determining a movement of a vehicle, the apparatus being described in FIG. 1, for example.

The ascertaining device 120 is designed to ascertain and provide the level signals 122, 124, 126 using the sensor signals 110, 112, 114. According to the exemplary embodiment shown, the apparatus, in this case, by way of example, the ascertaining device 120, comprises an activity recognition device 240 designed to ascertain an activity signal 244 using at least one of the sensor signals 110, 112, 114, and optionally using an external signal 242, and to provide the activity signal for ascertaining the level signals 122, 124, 126. The activity signal 244 indicates a current activity of the vehicle, that is to say at the time the sensor signals 110, 112, 114 were or are being sensed. For example, the activity signal 244 indicates, as the activity, that the vehicle has stopped, the vehicle is driving off road or the vehicle is driving on a highway.

According to an exemplary embodiment, the ascertaining device 120 comprises an extraction device 246, a quantization device 248, and an evaluation device 250. The extraction device 246 is designed to determine, using the sensor signals 110, 112, 114 and the activity signal 244, a first filtered sensor signal 252, a second filtered sensor signal 254 and a third filtered sensor signal 256 and to provide them to the quantization device 248. According to an exemplary embodiment, the filtered sensor signals 252, 254, 256 comprise noise-compromised portions of the sensor signals 110, 112, 114. The quantization device 248 is designed to perform a quantization of the noise portion of the filtered sensor signals 252, 254, 256, and to perform a characterization. By way of example, quantization device 248 is designed to quantify the filtered sensor signals 252, 254, 256 and ascertain a first quantization value 258 using the first filtered sensor signal 252, a second quantization value 260 using the second filtered sensor signal 254, and a third quantization value 262 using the third filtered sensor signal 256, and to provided them to the evaluation device 250. The evaluation device 250 is designed to ascertain the level signals 122, 124, 126 using the quantization values 258, 260, 262 as well as the activity signal 244. For example, to ascertain the level signals 122, 124, 126, the evaluation device 250 is designed to execute a summation over time and/or an evaluation so as to ascertain the level signals 122, 124, 126 as noise indicators.

According to an exemplary embodiment, the ascertaining device 120 is realized as part of an algorithm. The activity recognition performed in activity recognition device 240 allows the current situation or activity of the vehicle to be determined, wherein ideally a precisely-defined reference state, for example a stopped vehicle, is specified. This information is then used in extraction device 246, which represents a block for noise extraction, to identify the portion of the signals deemed to be noise-compromised. This portion of the signals is provided in the form of filtered sensor signals 252, 254, 256. This contaminated signal is quantized and these values are passed on to the last function block, in this case the evaluation device 250, which is responsible for the evaluation. According to an exemplary embodiment, each of the sensor signals 252, 254, 256 is quantized. Noise indicators are output, in this case in the form of level signals 122, 124, 126, which are strongly correlated to the noise level of the signals in the temporal profile.

According to an exemplary embodiment, after filtering in the extraction device 246, each contaminated signal obtained which has a high noise portion is processed in order to estimate the present noise level, for example an RMS calculation may be performed (quantization) using quantization device 248, for example. In addition to this, as an option other information such as peak-to-peak spacing, mean value, Root Allan variance, etc., are calculated. A programmable time window may be considered in which all calculations may be performed. The size of the time window gives control over the type of noise that can be corrected.

Finally, the evaluation function block, for example, the evaluation device 250, analyzes the RMS values, or another statistical value that was obtained from the quantization function block, and produces noise indicators of the signals, in this case in the form of level signals 122, 124, 126 which can be used in the fusion and/or selection of the final signal.

There are two ways to calculate a noise indicator here:

In accordance with a first exemplary embodiment, each RMS value, in this case each of the quantization values 258, 260, 262, is compared to certain threshold values defined, for example, according to the ID number of the activity, wherein values below the threshold values are considered “good” and values above are indicative of a degraded noise level. Each noise indicator may be calculated as a difference between the RMS value and the threshold values.

According to a second exemplary embodiment, a reference value, such as the median, is ascertained from all available RMS values, in this case those from each of the quantization values 258, 260, 262. The difference between the individual RMS values and the reference value is calculated and used as the noise indicator.

As already mentioned, the noise indicators, along with the sensitivity, offset, etc., indicators, may be used in the selection/fusion of the algorithm in order to give a higher weighting/priority to the signals with less noise.

The noise indicators, or even the RMS values, may also be compared to a safety threshold value to check if the sensor is erroneous with respect to the expected noise. For example, each noise indicator is compared to a safety threshold value. If the difference is greater than the threshold value, a counter is increased. If the difference is less than the threshold value, the counter is decreased. If the counter reaches a particular calibratable value, the signal associated with this counter may be identified as an “affected signal” or as invalid.

To account for the temperature dependence of the noise behavior, the sensor temperature may additionally be used. Based on the temperature, the parameterization of the functionality may be varied, for example the threshold values for activity recognition, the band pass parameters, and most importantly, the threshold values for calculating the noise indicator.

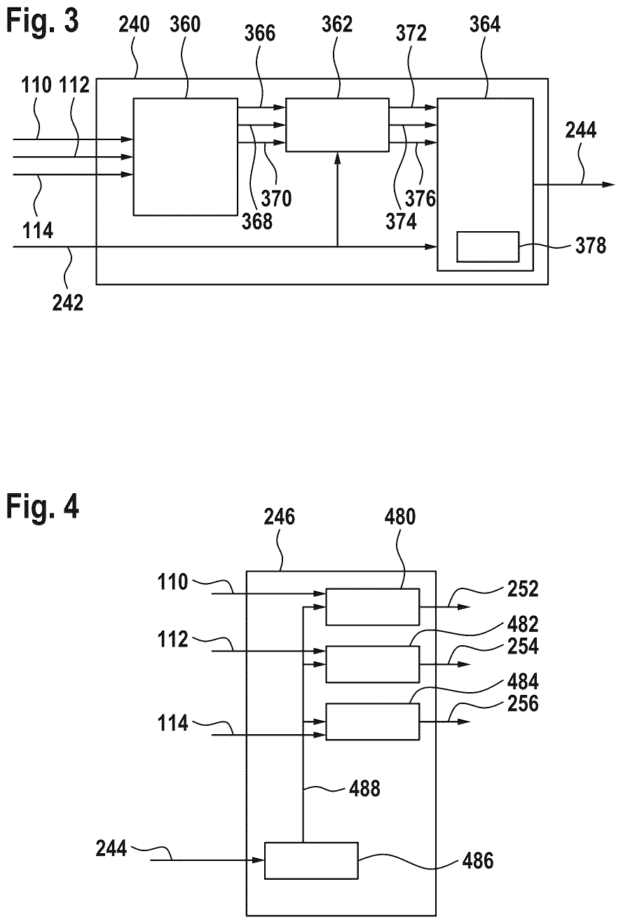

FIG. 3 shows a block diagram of an activity recognition device 240 according to an exemplary embodiment. This device is in this case the activity recognition device 240 described in FIG. 2.

According to an exemplary embodiment, the activity recognition device 240 comprises a filtering device 360, a comparison device 362, and a recognition device 364. The filtering device 360 is designed to filter the sensor signals 110, 112, 114 and provide a first filter signal 366, a second filter signal 368, and a third filter signal 370. To this end, the filtering device 360 comprises at least one filter, for example a low pass filter. According to an exemplary embodiment, the comparison device 362 is designed to carry out a threshold value comparison. For example, the comparison device 362 is designed to compare the filter signals 366, 368, 370 with at least one threshold value in order to obtain and provide a first comparison result 372, a second comparison result 374 and a third comparison result 376. Exactly the same threshold value may be used for all filter signals 366, 368, 370, or a separate threshold value may be provided for each of the filter signals 366, 368, 370, for example. The recognition device 364 is designed to determine the activity signal 244 using the comparison results 372, 374, 376. For example, the recognition device 364 is designed as an activity decision logic unit and comprises at least one timer 378, also referred to as a timing circuit.

The activity recognition device 240 is thus used to ascertain activity and is also referred to as an activity recognition block. The goal of this block is to recognize situations, i.e., reference states, in which the sensor signals 252, 254, 256 exhibit expected, known values and/or behaviors. For example, if the vehicle is waiting at a red light or is in its final position, the acceleration and rotation rate signals will be near zero for at least a few seconds. External information, such as information received from the ESP (standstill information) or from the navigation system may also be used to recognize a situation or to check the plausibility of the behavior of the signals. The external signal 242 is used for this purpose, for example.

Based on this information and on calibratable threshold values, the actual activity of the vehicle can be classified: for example no movement, off-road, highway, unknown. Each classification can be assigned an ID number and this information can be shared with the next functional blocks.

To this end, FIG. 3 shows steps of the activity recognition block. Thus, sensor signals 252, 254, 256 of different channels and of different types, such as acceleration and angular velocity in all directions, are filtered and then compared to threshold values. Using timers 378, the length of time that signals lie below or above certain threshold values may be counted, and the prerequisites for updating a classification can be established.

FIG. 4 shows a block diagram of an exemplary embodiment of an extraction device 246 as described, for example, with reference to FIG. 2. The extraction device 246 is designed to determine and provide the filtered sensor signals 252, 254, 256 using the sensor signals 110, 112, 114 and the activity signal 244. Optionally, the sensor signals 110, 112, 114 are redundant signals. Accordingly, the inertial sensors may represent redundant sensors.

According to an exemplary embodiment, the extraction device 246 comprises a first filter 480, a second filter 482, and a third filter 484, each of which operates as a band pass filter, by way of example. The first filter 480 is used to filter the first sensor signal 110 to obtain the first filtered sensor signal 252, the second filter 482 is used to filter the second sensor signal 112 to obtain the second filtered sensor signal 254, and the third filter 484 is used to filter the third sensor signal 114 to obtain the third filtered sensor signal 256.

Optionally, the extraction device 246 includes a parameterization device 486 designed to determine appropriate settings of the filters 480, 482, 484 using the activity signal 244, which, for example, represents an activity recognition, and provide corresponding setting values 488 to the filters 480, 482, 484.

According to an exemplary embodiment, the extraction device 246 represents a block for noise extraction in which (band pass) filters are used to view the frequency range of each of the sensor signals 252, 254, 256 in which the noise or contaminating signal occurs. As an option, according to an exemplary embodiment the cutoff frequency of these filters 480, 482, 484 is adjusted according to the activity ID number provided via the activity signal 244.

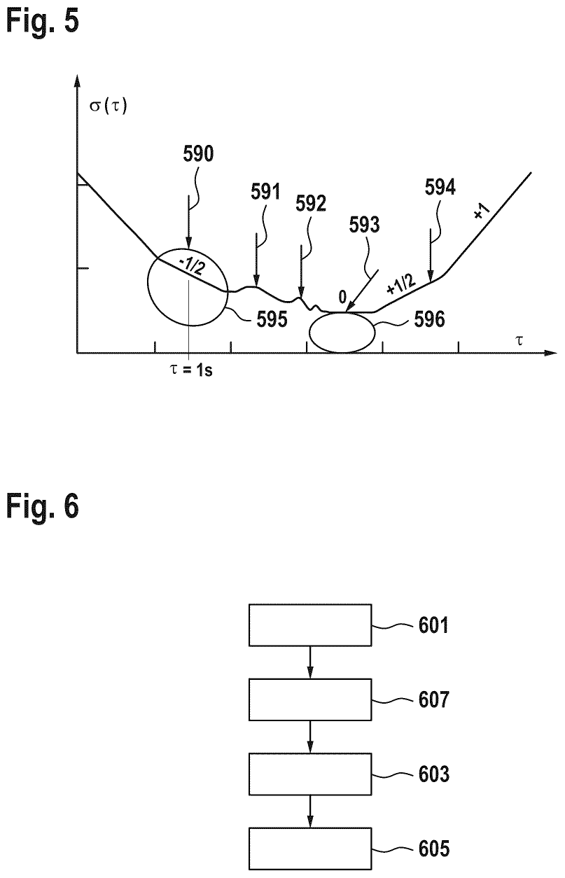

FIG. 5 shows a representation of a Root Allan variance σ(t) over the integration time τ according to an exemplary embodiment. It shows a thermal noise 590, a correlated noise 591, a sinusoidal section 592, an electric flicker 593, and a random movement 594, as well as an oblique random movement 595 and a biasing instability 596.

FIG. 6 shows a flowchart of a method for determining a movement of a vehicle according to an exemplary embodiment. The method may be implemented using an apparatus as described in the previous figures, for example.

In a step 601, sensor signals provided by inertial sensors are read in. In a step 603, using the sensor signals and an activity signal representing an activity of the vehicle, a level signal representing a noise level of the respective sensor signal is ascertained for each of the sensor signals. For example, step 603 may be implemented using an ascertaining device described above. In a step 605, a movement signal representing the movement of the vehicle is determined. The sensor signal and the level signals are used for this purpose. For example, step 603 may be implemented using a determination device described above. Optionally, the activity signal is ascertained and provided in a step 607, for example using an activity recognition device described above.

What is claimed is:

1. A method for determining a movement of a vehicle, comprising:
reading in a first sensor signal via an interface to a first inertial sensor of the vehicle and a second sensor signal via an interface to a second inertial sensor of the vehicle;
ascertaining a first level signal representing a noise level of the first sensor signal and a second level signal representing a noise level of the second sensor signal using the first sensor signal, the second sensor signal and an activity signal representing an activity of the vehicle; and
determining a movement signal representing the movement of the vehicle using the first sensor signal, the second sensor signal, the first level signal, and the second level signal.

2. The method according to claim 1, further comprising:
providing the activity signal using at least one of the sensor signals.

3. The method according to claim 2, wherein:
in the providing step, the at least one sensor signal is filtered and then a comparison is made with at least one threshold value, wherein the activity of the vehicle is recognized depending on a result of the comparison.

4. The method according to claim 1, wherein:
in the providing step, the activity is recognized as a stopped vehicle, an off-road driving of the vehicle, or a highway driving of the vehicle.

5. The method according to claim 1, wherein:
in the ascertaining step, a first filter is set for filtering the first sensor signal and a second filter is set for filtering the second sensor signal using the activity signal, the first sensor signal is filtered using the first filter to obtain a first filtered sensor signal, the second sensor signal is filtered using the second filter to obtain a second filtered sensor signal, and the first level signal is ascertained using the first filtered sensor signal and the second level signal is ascertained using the second filtered sensor signal.

6. The method according to claim 5, wherein:
in the ascertaining step, the first filtered sensor signal is quantized to obtain a first quantization value and the second filtered sensor signal is quantized to obtain a second quantization value, the first level signal representing the first quantization value and the second level signal representing the second quantization value.

7. The method according to claim 1, wherein:
in the determining step, the first level signal is compared with a first threshold value defined using the activity signal to create a first quality value representing a quality of the first sensor signal and the second level signal is compared with a second threshold value defined using the activity signal to create a second quality value representing a quality of the second sensor signal, wherein the movement signal is determined using the first sensor signal, the second sensor signal, the first quality value and the second quality value.

8. The method according to claim 1, wherein:
in the determining step, a reference value is determined using the first level signal and the second level signal, a first noise indicator value is determined as the difference between the first level signal and the reference value, and a second noise indicator value is determined as the difference between the second level signal and the reference value, wherein the movement signal is determined using the first sensor signal, the second sensor signal, the first noise indicator value and the second noise indicator value.

9. The method according to claim 1, wherein:
in the determining step, a first error signal indicative of an error state of the first inertial sensor is determined using the first level signal, and a second error signal indicative of an error state of the second inertial sensor is determined using the second level signal.

10. The method according to claim 1, wherein:
in the reading-in step, a further sensor signal is read in via an interface to a further inertial sensor of the vehicle, and
in the ascertaining step, a further level signal representing a noise level of the further sensor signal is ascertained using the further sensor signal and the activity signal.

11. An apparatus configured to execute and/or control the steps of the method according to claim 1 in corresponding units.

12. A computer program configured to execute and/or control the steps of the method according to claim 1.

13. A machine-readable storage medium on which the computer program according to claim 12 is stored.
